(19) United States
(12) Patent Application Publication
(10) Pub. No.: US 2004/0165411 A1
(43) Pub. Date: Aug. 26, 2004

(54) Polyetherimide lamp socket assembly

(76) Inventors: Eric W. Heath, New Haven, IN (US); Mark C. Molinaro, Fort Wayne, IN (US)

Correspondence Address: Gregory S Bernabeo, Synnestvedt & Lechner, 1101 Market Street, Philadelphia, PA, 19107-2950, US

(21) Appl. No.: 10/472,330

(22) PCT Filed: Mar. 20, 2002
(86) PCT No.: PCT/US02/08639

(51) Int. Cl. G11C 13/04

(52) U.S. Cl. 365/110

(57) ABSTRACT

A lamp socket assembly (18) that can be used with a replaceable incandescent lamp (22) in applications where it is desirable or necessary to limit outgassing of the socket assembly. The socket assembly (18) comprises a plastic socket made from polyetherimide, with the socket having an opening (50) to receive a press-sealed end (40) of the incandescent lamp (22). A plurality of electrical contacts (34) are located in the opening (50) and the socket (18) also includes a plurality of terminals (36), each of which is electrically connected to one of the contacts. The socket (18) includes at least one flexible retaining member (52) located at the opening (50) to engage the press-sealed end (40) of the incandescent lamp (22) and thereby retain the lamp within the opening. The socket (18) comprises a housing (30) and a separate body (32) integrally attached to the housing, with both the body and housing being made from the polyetherimide.

### TECHNICAL FIELD

This invention relates to lamp sockets and, in particular, automotive lamp socket assemblies used in exterior lighting applications.

### BACKGROUND OF THE INVENTION

Outgassing of plastics used in exterior vehicle lighting applications is known to cause fogging of the lenses and/or reflectors which can adversely affect the appearance, aesthetics, and photometric performance of the overall lamp assembly. See, for example, U.S. Pat. No. 6,012,830 to Frazier which discloses a light shield for a vehicle headlamp that uses a titanium carbide coating that reportedly does not outgas over the life of the headlamp. Outgassing has been traced to the release of volatiles from the resin as a result of the polymerization process of some resins. This is particularly true where exterior vehicle incandescent lamps are used in conjunction with a plastic lamp socket, since the heat output of the lamps can raise the temperature of the socket to 200° F.-450° F.

Generally, the plastics used in conventional incandescent and other heat-producing lamp applications has been selected for their ability to work at elevated temperatures without softening or degradation of the plastic. See, for example, U.S. Pat. No. 4,795,939 to F. Eckhardt et al. which discloses the use of a high-temperature resistant plastic such as Ultem 2300™ and Ryton™ in a high-pressure discharge automotive headlamp. Polyetherimides such as Ultem™ has also been used in other vehicle headlamp applications, such as disclosed in U.S. Pat. No. 5,239,226 to D. Seredich et al., U.S. Pat. No. 4,795,388 to C. Coliandris et al., and U.S. Pat. No. 4,751,421 to A. Braun et al., each of which disclose a halogen headlamp base, or holder, made of Ultem™. See also, U.S. Pat. No. 5,889,360 to M. Frey et al. which discloses an arc tube having an integral socket made from polyetherimide. Apart from the lamps themselves, polyetherimide plastics have also been used for lamp reflectors, as disclosed in U.S. Pat. No. 4,982,132 to K. Meyer et al. and U.S. Pat. No. 4,774,636 to M. Gaugel et al.

### SUMMARY OF THE INVENTION

In accordance with the present invention, there is provided a lamp socket assembly that can be used with a replaceable incandescent lamp in applications where it is desirable or necessary to limit outgassing of the socket assembly. The socket assembly comprises a plastic socket made from polyetherimide, with the socket having an opening to receive a press-sealed end of an incandescent lamp. A plurality of electrical contacts are located in the opening and the socket also includes a plurality of terminals, each of which is electrically connected to one of the contacts. The socket includes at least one flexible retaining member located at the opening to engage the press-sealed end of the incandescent lamp and thereby retain the lamp within the opening. Preferably, the socket comprises a housing and a separate body integrally attached to the housing, with both the body and housing being made of polyetherimide.

In accordance with another aspect of the present invention, there is provided an automotive lamp assembly that includes a lamp socket, an incandescent lamp removably mounted within the lamp socket, a reflector extending at least partially around the lamp, and a lens, with the lamp socket again being made from polyetherimide.

### BRIEF DESCRIPTION OF THE DRAWINGS

Preferred exemplary embodiments of the invention will hereinafter be described in conjunction with the appended drawings, wherein like designations denote like elements, and wherein:

FIG. 1 is a side view of an exterior vehicle lamp assembly constructed in accordance with the present invention and showing portions of the assembly in cross-section;

FIG. 2 is a cross-sectional view of one of the lamp sockets of FIG. 1; and

FIG. 3 is a cross-sectional view of an alternative embodiment of a lamp socket of the present invention.

### DETAILED DESCRIPTION OF THE PREFERRED EMBODIMENTS

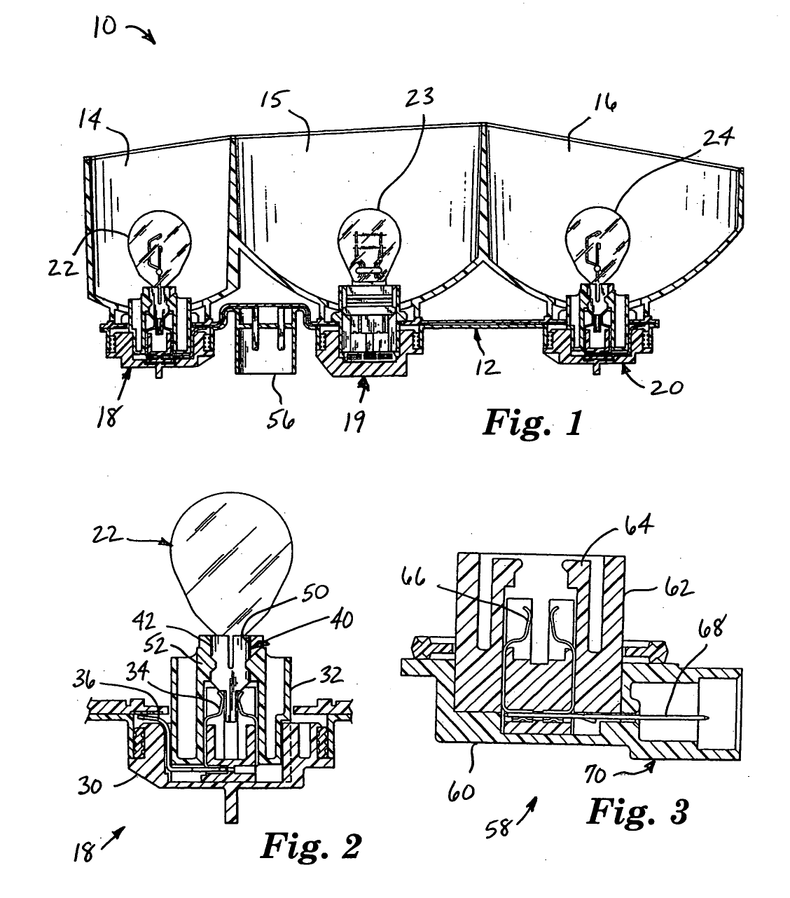

FIG. 1 depicts an exterior vehicle lamp assembly 10 such as can be used for rear vehicle lighting to provide separate, rearwardly-directed illumination for braking, turn signaling, and backing up. The assembly 10 includes a common backplate 12 to which is mounted three reflectors 14-16 that are formed as a unitary component with each of the three reflector sections 14-16 having a central opening in which is located a respective lamp socket 18-20. Each lamp socket is individually mounted to the common backplate 12 and each contains an incandescent lamp 22-24.

FIG. 2 depicts further details of one of the lamp sockets 18 and its associated lamp 22. As shown therein, the lamp socket 18 is actually a socket assembly formed from a housing 30, a body 32 mounted in the housing, a set of electrical contacts 34 within the body 32 to deliver power to the lamp 18, and a corresponding set of terminals 36 (only one shown in the cross-sectional view) that are electrically connected to the contacts 34 to deliver power from the backplate to the contacts 34. The lamp 22 is an incandescent lamp having a press-sealed end 40 that includes a plastic sleeve 42 having a recessed channel that allows that lamp to be resiliently held in place within the lamp socket 18. Suitable bulb and sleeve designs for the lamp 22 are disclosed in U.S. Pat. No. 5,186,669 to M. R. Holman et al. and U.S. Pat. No. 5,486,991 to G. E. Talmon-Gros et al., the complete disclosures of which are hereby incorporated by reference. Suitable, existing GT-8 bulbs are also commercially available from the Wagner Lighting division of Federal-Mogul Corporation.

The lamp 22 is mounted in an opening 50 in the body 32 of the socket 18. Located within that opening 50 are the electrical contacts 34 as well as a pair of opposing flexible retaining members, or fingers, 52. These fingers each engage the sleeve 42 at the press-sealed end of the incandescent lamp 22 and thereby retain the lamp within the opening 50. This is accomplished as shown by providing each retaining finger 52 with a protrusion that faces the opposing finger and that snaps into its corresponding recessed channel on the sleeve 42 when the lamp 22 is inserted into the opening. Since the fingers 52 are flexible, the lamp is not an integral part of the socket, but is replaceable by exerting enough upward force on the lamp to cause the fingers to flex outwardly so that the press-sealed end of the lamp is able to move up and out of the socket 18.

The electrical contacts 34 are located within the body 32 and the terminals 36 are located within the housing 30 such that the contacts and terminals are separate components that connect together at the interface between the housing and body. However, each contact is associated with a terminal and other embodiments of the socket assembly could be used in which the contacts are unitary extensions of the terminals rather than separate components. The terminals are designed to mate with corresponding pads on the backplate 12 so that a single connector 56 can be used to supply power to all three sockets 18-20.

A more complete description of the assembly 10 in general and the sockets 18-20 and backplate 12 in particular is contained in U.S. Pat. No. 5,536,174 to Forish, the complete disclosure of which is hereby incorporated by reference. U.S. Pat. No. 6,139,334 to Forish et al. also discloses an alternative backplate and socket assembly which can also suitably be used without departing from the scope of the present invention, and the complete disclosure of that patent is hereby incorporated by reference. Also, rather than using a two-part socket assembly with both a housing and a body integrally attached to the housing, a single unitary housing could be used.

FIG. 3 shows an alternative embodiment of a lamp socket assembly 58 of the present invention which can be used in applications where the common backplate 12 is not used. As with the embodiment of FIG. 2, the socket assembly 58 of FIG. 3 includes a housing 60 and a body 62 with fingers 64, as well as electrical contacts 66 and terminals 68, but also includes a connector 70 that surrounds the terminals as a unitary part of the housing 60. A more complete description of lamp socket assembly 58 as well as additional socket embodiments is contained in U.S. Pat. No. 5,035,643 to Forish et al., the complete disclosure of which is hereby incorporated by reference.

In accordance with the invention, the lamp socket assemblies 18-20 and 60 are made from polyetherimide (PEI) such as is available from GE under the trademark Ultem. Preferably, both the housings 30, 60 and bodies 32, 62 are made from the polyetherimide, although it will be appreciated that both need not be so that, for example, a socket assembly can be constructed with only the body 32, 62 made from the polyetherimide. The use of polyetherimide resins in the molding of plastic components is known to those skilled in the art and conventional molding processes can be used to manufacture the lamp sockets. Since, as is known, the polyetherimide resin is molded using higher temperatures than the plastics conventionally used for these lamp sockets, an oil-cooled mold can be used in the molding process. This and other necessary or desirable modifications of the standard lamp socket molding process will be apparent to those skilled in the art.

The resulting PEI lamp socket assembly has been found to work well in the operating temperature range of 200° F.-450° F. for these types of automotive lamp sockets without exhibiting outgassing as normally occurs with conventional lamp socket plastics. Testing has shown no visible impact to the surface of the reflector or lens.

It will thus be apparent that there has been provided in accordance with the present invention a polyetherimide lamp socket assembly which achieves the aims and advantages specified herein. It will of course be understood that the foregoing description is of preferred exemplary embodiments of the invention and that the invention is not limited to the specific embodiments shown. Various changes and modifications will become apparent to those skilled in the art. For example, the backplate could also be made from the polyetherimide resin. All such variations and modifications are intended to come within the scope of the appended claims.

1. A lamp socket assembly for use with a separate, replaceable incandescent lamp, said socket assembly comprising:
a plastic socket made from polyetherimide and having an opening to receive a press-sealed end of an incandescent lamp;
a plurality of electrical contacts located in said opening; and
a plurality of terminals, each of which is electrically connected to one of said contacts;
wherein said socket includes at least one flexible retaining member located at said opening to engage the press-sealed end of the incandescent lamp and thereby retain the lamp within said opening.

2. A lamp socket assembly as defined in claim 1, wherein the press-sealed end of the lamp includes a plastic sleeve.

3. A lamp socket assembly as defined in claim 1, wherein each of said terminals is associated with one of said contacts and wherein each terminal and associated contact comprise separate components electrically connected to each other.

4. A lamp socket assembly as defined in claim 1, wherein said socket comprises a housing and a separate body integrally attached to said housing, said body and housing both being made of polyetherimide.

5. A lamp socket assembly as defined in claim 4, wherein said electrical contacts are located in said body and said terminals are located in said housing.

6. An automotive lamp assembly, comprising:
a lamp socket;
an incandescent lamp removably mounted within said lamp socket;
a reflector extending at least partially around said lamp; and
a lens, wherein said lamp socket is made from polyetherimide.

7. An automotive lamp assembly as defined in claim 6, further comprising:
a plurality of electrical contacts located in an opening in said lamp socket; and
a plurality of terminals, each of which is electrically connected to one of said contacts;
wherein said socket includes at least one flexible retaining member located at said opening to engage the incandescent lamp and thereby retain the lamp within said opening.

8. An automotive lamp assembly as defined in claim 7, wherein the lamp includes a press-sealed end having a plastic sleeve in contact with said retaining member(s).

9. An automotive lamp assembly as defined in claim 7, wherein each of said terminals is associated with one of said contacts and wherein each terminal and associated contact comprise separate components electrically connected to each other.

10. An automotive lamp assembly as defined in claim 6, wherein said socket comprises a housing and a separate body integrally attached to said housing, said body and housing both being made of polyetherimide.

11. An automotive lamp assembly as defined in claim 6, further comprising a backplate, wherein said socket is mounted to said backplate.

12. An automotive lamp assembly as defined in claim 6, further comprising:
a plurality of electrical contacts located in an opening in said lamp socket;
a plurality of terminals, each of which is electrically connected to one of said contacts; and
at least one flexible retaining member located at said opening to engage the incandescent lamp and thereby retain the lamp within said opening.

13. A lamp socket assembly for use with a separate, replaceable incandescent lamp, said socket assembly comprising:
a plastic socket made from polyetherimide, said socket comprising a housing and a body integrally attached to said housing, said body having an opening to replaceably receive a press-sealed end of a replaceable incandescent lamp;
a plurality of electrical contacts located in said opening; and
a plurality of terminals, each of which is electrically connected to one of said contacts.

14. A lamp socket assembly as defined in claim 13, wherein the press-sealed end of the lamp includes a plastic sleeve.

15. A lamp socket assembly as defined in claim 13, further comprising at least one flexible retaining member located at said opening to engage the press-sealed end of the incandescent lamp and thereby retain the lamp within said opening.

16. A lamp socket assembly as defined in claim 13, wherein the press-sealed end of the lamp includes a plastic sleeve positioned to contact said flexible retaining member.

17. An automotive lamp assembly, comprising:
a lamp socket made from polyetherimide, said lamp socket comprising said socket comprising a housing and a body integrally attached to said housing, said body having an opening to removably receive a press-sealed end of a replaceable incandescent lamp;
an incandescent lamp removably mounted within said lamp socket;
a reflector extending at least partially around said lamp; and
a lens.

18. A lamp socket assembly as defined in claim 17, wherein the press-sealed end of the lamp includes a plastic sleeve.

19. A lamp socket assembly as defined in claim 17, further comprising at least one flexible retaining member located at said opening to engage the press-sealed end of the incandescent lamp and thereby retain the lamp within said opening.

20. A lamp socket assembly as defined in claim 17, wherein the press-sealed end of the lamp includes a plastic sleeve in contact with said flexible retaining member.
